(19) United States
(12) Patent Application Publication
(10) Pub. No.: US 2026/0324453 A1
(43) Pub. Date: Oct. 15, 2026

(54) SEMICONDUCTOR DEVICE

(71) Applicant: ROHM CO., LTD., Kyoto-shi (JP)

(72) Inventors: Maki MITA, Kyoto-shi (JP); Norio IMO, Kyoto-shi (JP); Moe MIKAMI, Kyoto-shi (JP)

(21) Appl. No.: 19/466,988

(22) Filed: Feb. 2, 2026

Related U.S. Application Data
(63) Continuation of application No. PCT/JP2024/027293, filed on Jul. 31, 2024.

(30) Foreign Application Priority Data
Aug. 8, 2023 (JP) 2023-129231

(51) Int. Cl. H10W 70/40; H10W 72/00; H10W 74/10; H10W 90/00

(52) U.S. Cl. CPC H10W 70/424; H10W 70/417; H10W 72/884; H10W 74/114; H10W 90/736; H10W 90/756

(57) ABSTRACT

A semiconductor includes a plurality of first leads, a semiconductor element, and a sealing resin. The first lead includes a first lead first surface facing the first side in the thickness direction and exposed from a resin first surface, a first lead second surface facing the second side in the thickness direction, and a first lead first end surface located between the first lead first surface and the first lead second surface in the thickness direction, facing outward in the first direction, and exposed from a resin side surface. The first lead first surface includes a first narrow portion connected to the first lead first end surface, and a first wide portion located on an inner side in the first direction relative to the first narrow portion. The first narrow portion includes a first end edge adjoining the first end surface. The first end edge has a first width in a second direction, the first wide portion has a second width in the second direction, and the first width is smaller than the second width.

### TECHNICAL FIELD

The present disclosure relates to a semiconductor device.

### BACKGROUND ART

An example of a conventional semiconductor device is disclosed in JP-A-2022-146271. The semiconductor device disclosed in the document includes a plurality of leads, a semiconductor element, and a resin member. The plurality of leads are electrically connected to the semiconductor device. The bottom surface in the thickness direction and the end surface of each lead are exposed from the resin member.

### BRIEF DESCRIPTION OF THE DRAWINGS

FIG. 1 is a plan view of a semiconductor device according to a first embodiment of the present disclosure.

FIG. 2 is a partial plan view of the semiconductor device according to the first embodiment of the present disclosure.

FIG. 3 is a bottom view of the semiconductor device according to the first embodiment of the present disclosure.

FIG. 4 is a sectional view taken along line IV-IV in FIG. 2.

FIG. 5 is a partial enlarged sectional view of the semiconductor device according to the first embodiment of the present disclosure.

FIG. 6 is a plan view showing an example of a first lead of the semiconductor device according to the first embodiment of the present disclosure.

FIG. 7 is a bottom view showing the example of the first lead of the semiconductor device according to the first embodiment of the present disclosure.

FIG. 8 is a sectional view taken along line VIII-VIII in FIG. 6.

FIG. 9 is a plan view showing another example of the first lead of the semiconductor device according to the first embodiment of the present disclosure.

FIG. 10 is a partial enlarged plan view showing an example of a method for manufacturing the semiconductor device according to the first embodiment of the present disclosure.

FIG. 11 is a partial enlarged sectional plan view showing the example of a method for manufacturing the semiconductor device according to the first embodiment of the present disclosure.

FIG. 12 is a partial enlarged sectional view showing a first variation of the semiconductor device according to the first embodiment of the present disclosure.

FIG. 13 is a bottom view showing a first variation the first lead of the semiconductor device according to the present disclosure.

FIG. 14 is a bottom view showing a second variation the first lead of the semiconductor device according to the present disclosure.

FIG. 15 is a bottom view showing a third variation the first lead of the semiconductor device according to the present disclosure.

### DETAILED DESCRIPTION OF EMBODIMENTS

Preferred embodiments of the present disclosure are described below with reference to the accompanying drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

First embodiment:

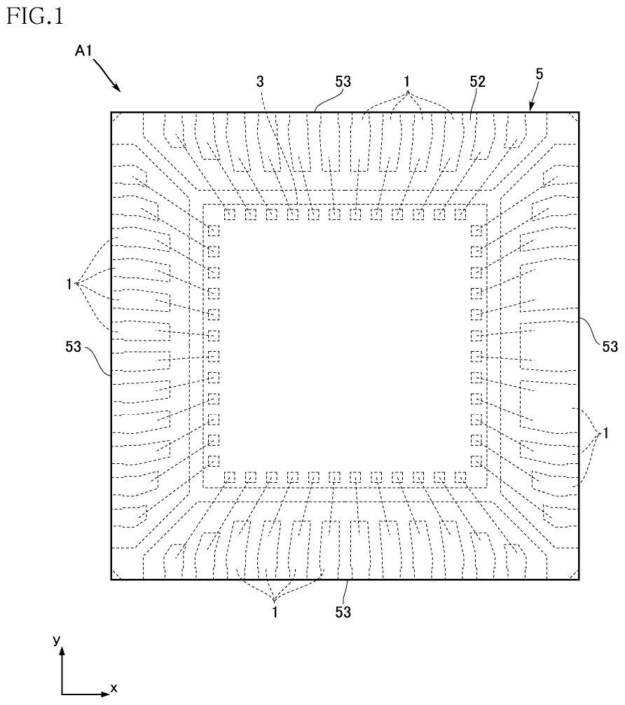

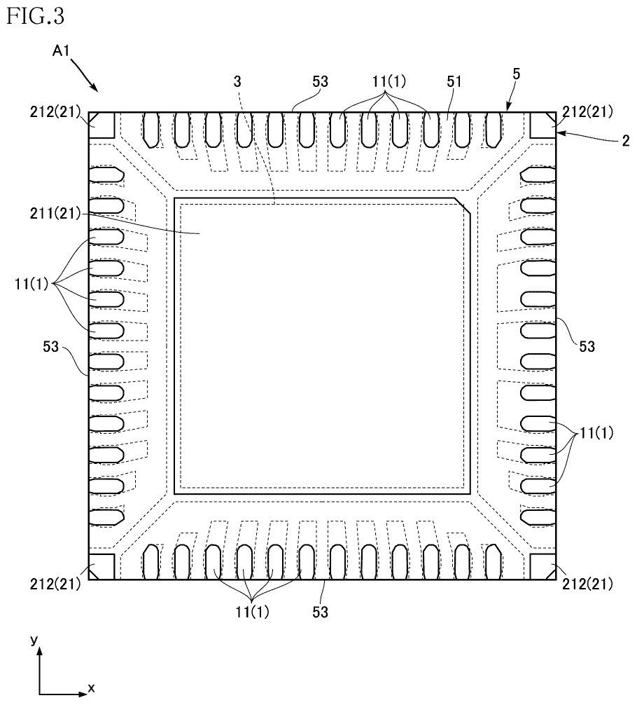

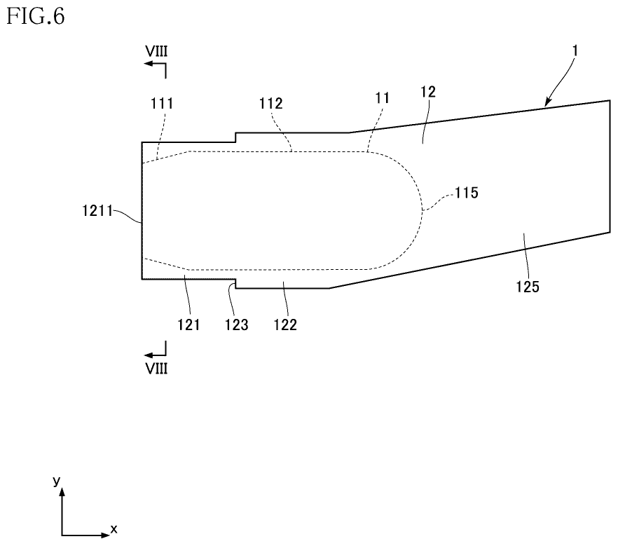

FIGS. 1 to 9 show a semiconductor device according to a first embodiment of the present disclosure. The semiconductor device A1 of the present embodiment includes a plurality of first leads 1, a semiconductor element 3, and a sealing resin 5. The semiconductor device A1 also includes a second lead 2 and a plurality of wires 4.

The application, function, and specific configuration of the semiconductor device A1 are not particularly limited. The package type of the semiconductor device A1 of the illustrated example is the QFN (Quad Flat Non-lead package), but any other package type may be used.

An example of the thickness direction of the present disclosure is defined as a z direction. A first side in the z direction is referred to as a z1 side, and a second side opposite to the first side in the z direction is referred to as a z2 side. An example of a direction intersecting the z direction is defined as an x direction. The direction orthogonal to the z direction and the x direction may be defined as a y direction. In the present embodiment, one of the x direction and the y direction may be the first direction of the present disclosure, and the other may be the second direction of the present disclosure.

The sealing resin 5 covers a part of each of the first leads 1, a part of the second lead 2, the semiconductor element 3, and the wires 4. The sealing resin 5 has an electrically insulating property. The sealing resin 5 includes, for example, black epoxy resin. As shown in FIGS. 1 to 5, in the present embodiment, the sealing resin 5 has a resin first surface 51, a resin second surface 52, and a plurality of resin side surfaces 53. The specific shape of the sealing resin 5 is not particularly limited. In the illustrated example, it is rectangular as viewed in the z direction.

The resin first surface 51 faces the z2 side in the z direction. The resin second surface 52 faces the z1 side in the z direction. The resin side surfaces 53 face in the x direction or the y direction. In the illustrated example, the sealing resin 5, which is rectangular as viewed in the z direction, has four resin side surfaces 53.

The first leads 1 are electrically connected to the semiconductor element 3. The first leads 1 may contain a metal such as Cu (copper), Ni (nickel), Fe (iron), or an alloy of these. In the present embodiment, the first leads 1 are mainly composed of Cu (copper). As shown in FIGS. 1 to 3, in the present embodiment, the first leads 1 are arranged along the x direction or the y direction. For the first leads 1 arranged along the x direction, the y direction corresponds to the first direction of the present disclosure, and the x direction corresponds to the second direction of the present disclosure. For the first leads 1 arranged along the y direction, the x direction corresponds to the first direction of the present disclosure, and the y direction corresponds to the second direction of the present disclosure.

FIGS. 5 to 8 show one of first leads 1 arranged along the y direction. A first lead 1 has a first surface 11, a second surface 12, and a first end surface 13. The first lead 1 of the illustrated example further has an intermediate surface 14 and two side surfaces 15.

The first surface 11 faces the z2 side in the z direction. The first surface 11 is exposed from the resin first surface 51 of the sealing resin 5. In the illustrated example, the first surface 11 and the resin first surface 51 are flush with each other.

The first surface 11 has a first narrow portion 111 and a first wide portion 112.

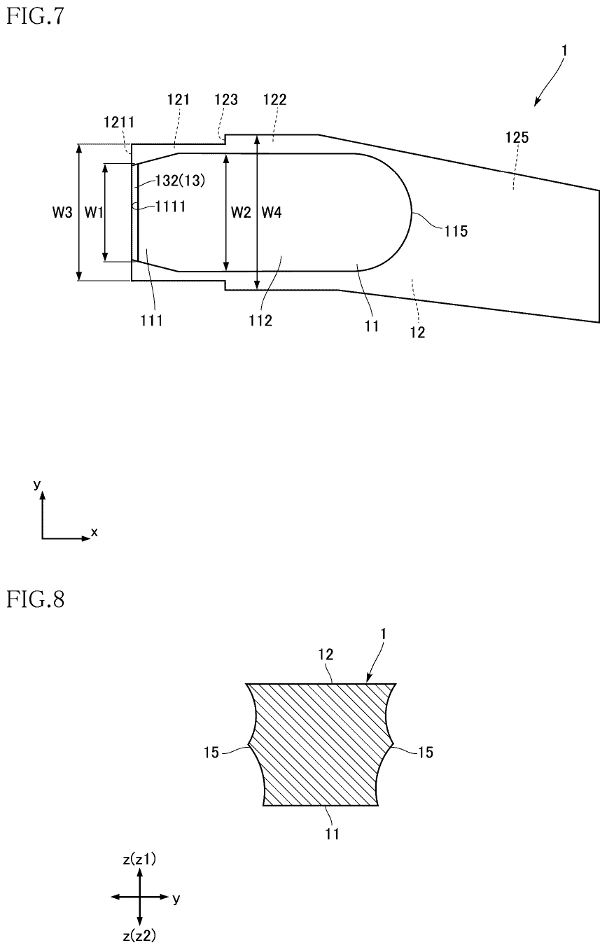

The first narrow portion 111 is connected to the first end surface 13. The first narrow portion 111 has a first end edge 1111. The first end edge 1111 forms the boundary between the first surface 11 and the first end surface 13. The specific shape of the first narrow portion 111 is not particularly limited. In the illustrated example, the first narrow portion 111 has a tapered shape where its size in the y direction decreases from the inner side toward the outer side in the x direction (from the right side to the left side in FIG. 7).

The first wide portion 112 is connected to the first narrow portion 111 on the inner side in the x direction (the right side in FIG. 7). The specific shape of the first wide portion 112 is not particularly limited. In the illustrated example, the first wide portion 112 has a constant size in the y direction.

As shown in FIG. 7, the first width W1, which is the size in the y direction of the first end edge 1111, is smaller than the second width W2, which is the size in the y direction of the first wide portion 112. The specific values of the first width W1 and the second width W2 are not particularly limited. For example, the first width W1 is not less than 0.10 mm and not more than 0.12 mm, and the second width W2 is not less than 0.18 mm and not more than 0.20 mm.

In the illustrated example, the first surface 11 further has an arc-shaped portion 115. The arc-shaped portion 115 is connected to the first wide portion 112 on the inner side in the x direction. The arc-shaped portion 115 has a shape bulging inward in the x-direction.

The second surface 12 has a second narrow portion 121, a second wide portion 122, a second stepped portion 123, and an inclined portion 125.

The second narrow portion 121 is connected to the first end surface 13. The second narrow portion 121 has a second end edge 1211. The second end edge 1211 forms the boundary between the second surface 12 and the first end surface 13. The specific shape of the second narrow portion 121 is not particularly limited. In the illustrated example, the second narrow portion 121 has a constant size in the y direction.

The second wide portion 122 is connected to the second narrow portion 121 on the inner side in the x direction (the right side in FIG. 7). The specific shape of the second wide portion 122 is not particularly limited. In the illustrated example, the second wide portion 122 has a constant size in the y direction.

The second stepped portion 123 is interposed between the second narrow portion 121 and the second wide portion 122. The second stepped portion 123 has a bent outline.

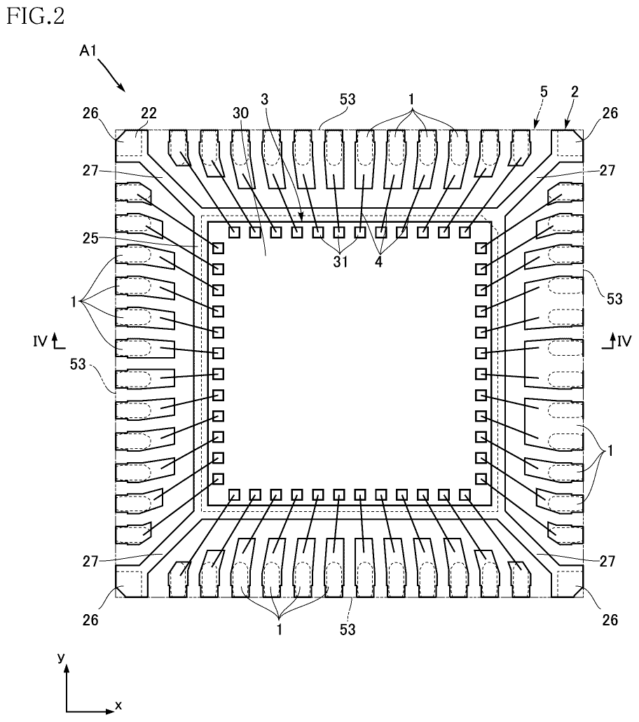

The inclined portion 125 is connected to the second wide portion 122 on the inner side in the x direction (the right side in FIG. 7). The inclined portion 125 is inclined with respect to the y direction. As understood from FIG. 2, the extension of the inclined portion 125 passes through a position closer to the center of the semiconductor element 3 as compared with the extension in the first direction of the second wide portion 122.

As shown in FIG. 7, the third width W3, which is the size in the y direction of the second end edge 1211, is smaller than the fourth width W4, which is the size in the y direction of the second wide portion 122. The first width W1 is smaller than the third width W3, and the second width W2 is also smaller than the third width W3 in the illustrated example. The specific values of the third width W3 and the fourth width W4 are not particularly limited. For example, the third width W3 is not less than 0.24 mm and not more than 0.26 mm, and the fourth width W4 is not less than 0.21 mm and not more than 0.23 mm.

The sizes and positional relationship of the first surface 11 and the second surface 12 in the first direction (the x direction in FIG. 7) are not particularly limited. In the illustrated example, the size in the x direction of the second surface 12 is larger than the size in the x direction of the first surface 11. The size in the x direction of the second narrow portion 121 is larger than the size in the x direction of the first narrow portion 111.

As shown in FIG. 5, the first end surface 13 is located between the first surface 11 and the second surface 12 in the z direction. The first end surface 13 is connected to the first surface 11 and the second surface 12. The first end surface 13 faces outward in the first direction (the left side in FIG. 5). The specific shape and size of the first end surface 13 are not particularly limited. In the illustrated example, the first end surface 13 includes a flat region 131 and a recessed region 132.

The flat region 131 is a region connected to the second surface 12, and is flat along the y direction and the z direction. In the illustrated example, the flat region 131 is flush with the resin side surface 53.

The recessed region 132 is a region connected to the first surface 11, and is connected to the flat region 131 on the z1 side in the z direction. The recessed region 132 is recessed inward in the first direction (to the right side in the x direction in FIG. 7) relative to the flat region 131. In a case where the first end surface 13 has the recessed region 132, a plating layer containing a metal such as Sn (tin) may be provided on the recessed region 132 and the first surface 11.

As shown in FIG. 5, the intermediate surface 14 is located between the first surface 11 and the second surface 12 in the z direction and connected to the first surface 11 and the second surface 12 on the inner side in the first direction (the right side in the x direction in FIG. 5). The specific shape of the intermediate surface 14 is not particularly limited. In the illustrated example, the intermediate surface 14 is inclined with respect to the z direction. The portion on the z2 side in the z direction of the intermediate surface 14 has a smooth concave shape, and the portion on the z1 side in the z direction has a smooth convex shape.

As shown in FIG. 8, each of the two side surfaces 15 is located between the first surface 11 and the second surface 12 in the z direction and connected to the first surface 11 and the second surface 12. The specific shape of the side surface 15 is not particularly limited. In the illustrated example, the side surface 15 has two concave portions arranged in the z direction. Such a side surface 15 may be formed, for example, when the first lead 1 is formed by etching.

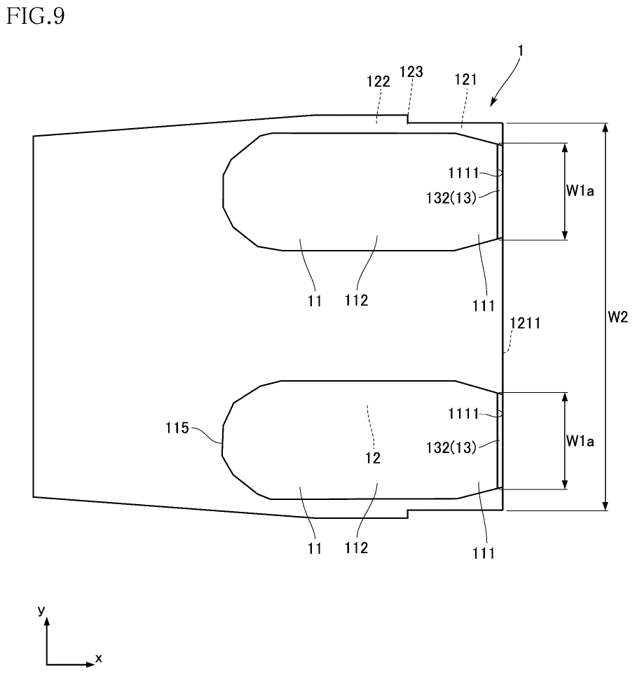

FIG. 9 shows another one of the first leads 1. The illustrated first lead 1 has two first surfaces 11.

In this first lead 1, the x direction corresponds to the first direction. The two first surfaces 11 are spaced apart from each other in the y direction, which corresponds to the second direction. Each of the two first surfaces 11 has the first narrow portion 111. The size in the y direction of the first end edge 1111 of each first narrow portion 111 is defined as a width W1a. In this first lead 1, the first width W1 of the first narrow portions 111 is the sum of the two widths W1a.

The second lead 2 has the semiconductor element 3 mounted on it. The second lead 2 may contain a metal such as Cu (copper), Ni (nickel), Fe (iron), or an alloy of these. In the present embodiment, the second lead 2 is mainly composed of Cu (copper).

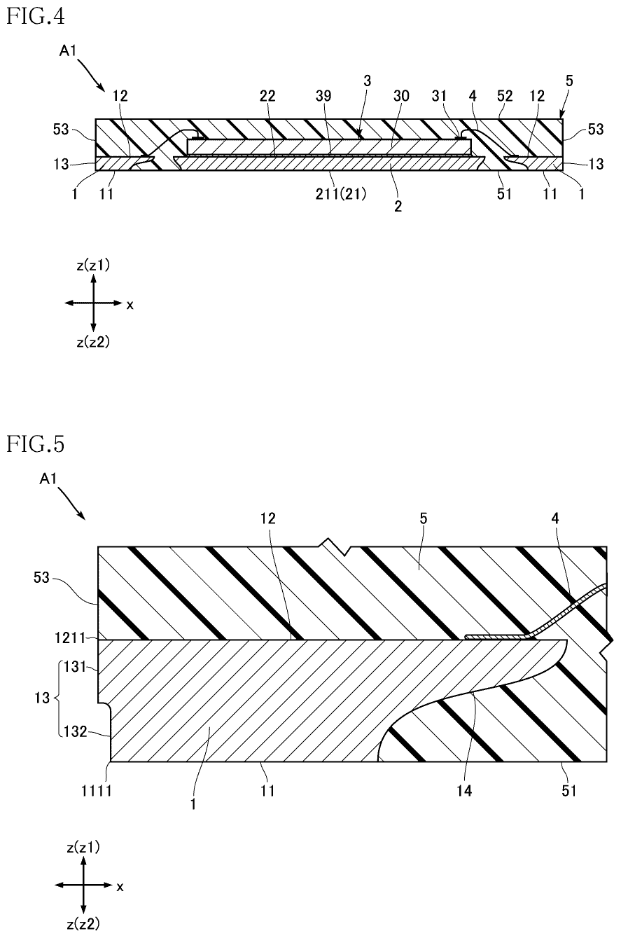

As shown in FIG. 4, the second lead 2 has a third surface 21 and a fourth surface 22. The third surface 21 faces the z2 side in the z direction and is exposed from the resin first surface 51. In the illustrated example, the third surface 21 is flush with the resin first surface 51. The fourth surface 22 faces the z1 side in the z direction.

As shown in FIGS. 2 to 4, the second lead 2 of the illustrated example has an island portion 25, a plurality of corner portions 26, and a plurality of connecting portions 27.

The island portion 25 is disposed on the inner side in the first direction relative to the first leads 1. In the illustrated example, the first leads 1 are arranged along the x direction and the y direction to form a quadrilateral shape, and the island portion 25 is disposed at the center of the quadrilateral.

The corner portions 26 are disposed at the four corners of the resin first surface 51. The corner portions 26 are exposed from the resin first surface 51 and the resin side surfaces 53. The number of corner portions 26 is not particularly limited, and is four in the illustrated example.

The connecting portions 27 individually connect the island portion 25 and the corner portions 26. In the illustrated example, the number of connecting portions 27 is four.

The third surface 21 includes a center region 211 and a plurality of corner regions 212. The center region 211 is a region of the third surface 21 that is included in the island portion 25. The corner regions 212 are regions of the third surface 21 that are included in the corner portions 26.

The semiconductor element 3 is an element that performs the electrical functions of the semiconductor device A1. The semiconductor element 3 is not limited to any particular configuration, and may take the form of various ICs (integrated circuit), LSIs (Large Scale Integrations), or similar devices. As shown in FIGS. 2 and 4, the semiconductor element 3 is mounted on a portion of the fourth surface 22 that is included in the third surface 21. In the illustrated example, the semiconductor element 3 is bonded to the fourth surface 22 with a bonding material 39. The bonding material 39 is, for example, solder or Ag (silver) paste.

The semiconductor element 3 has a main body 30 and a plurality of electrodes 31. The main body 30 is a part containing a semiconductor and formed with, for example, a circuit portion (not shown) that performs the electrical functions of the semiconductor element 3. The specific shape of the main body 30 is not particularly limited, and is rectangular as viewed in the z direction in the illustrated example.

The electrodes 31 are disposed on the z1-side portion of the main body 30 in the z direction. The electrodes 31 contain, for example, Au (gold) or Al (aluminum). In the illustrated example, the electrodes 31 are disposed along four sides of the main body 30.

The electrodes 31 of the semiconductor element 3 are electrically connected to the first leads 1. In the present embodiment, the electrodes 31 and the first leads 1 are individually electrically connected with wires 4. One end of each wire 4 is bonded to an electrode 31, and the other end of the wire 4 is bonded to the second surface 12 of a corresponding first lead 1. The wires 4 contain a metal such as Au (gold), Al (aluminum), or Cu (copper), for example. The electrical connection of the electrodes 31 and the first leads 1 is not limited to connection using wires 4. For example, the semiconductor element 3 may be mounted on the first leads 1 and the second lead 2 by flip-chip mounting.

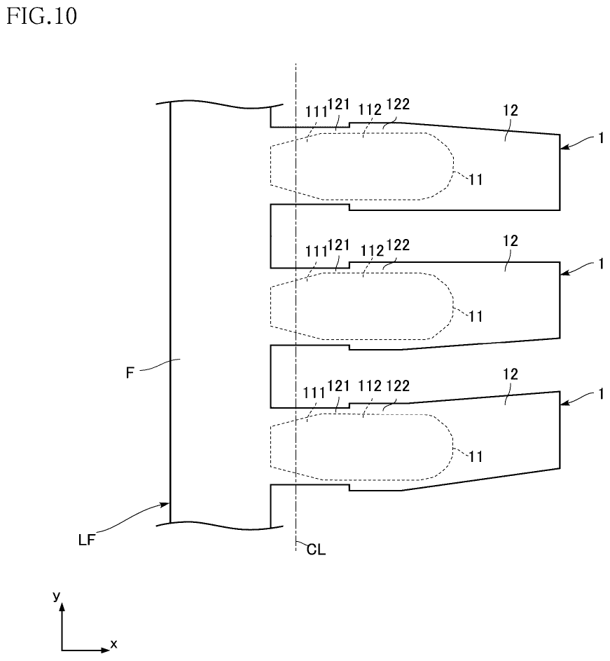

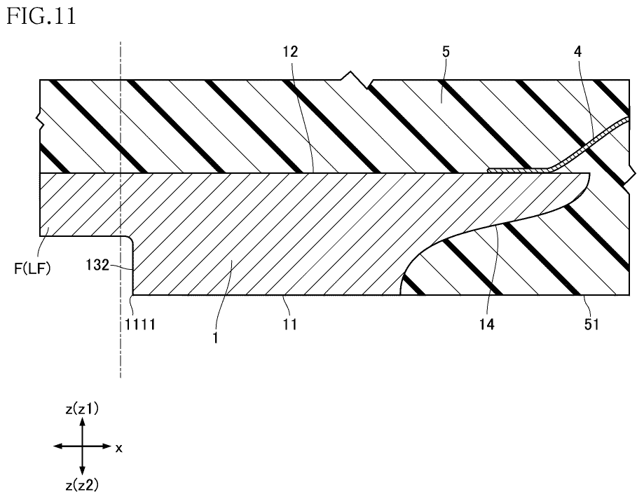

FIGS. 10 and 11 show steps of an example of a method for manufacturing the semiconductor device A1.

In an example of a method for manufacturing the semiconductor device A1, a lead frame LF is first prepared. The lead frame LF includes a plurality of first leads 1 and a plurality of second leads 2 in a quantity sufficient to manufacture a plurality of semiconductor devices A1. The lead frame LF includes a frame portion F. The frame portion F holds the first leads 1 and the second leads 2 as appropriate. FIG. 10 shows a part of the lead frame LF. Specifically, the figure shows a part of frame portion F extending in the y direction and holding three first leads 1.

As an example, a plurality of semiconductor elements 3 are individually mounted on the island portions 25 of the second leads 2 of the lead frame LF. Next, a plurality of wires 4 are bonded. Next, a sealing resin 5 is formed to cover a part of the lead frame LF, the semiconductor elements 3, and the wires 4.

After the sealing resin 5 is formed, a dicing process is performed by cutting the lead frame LF and the sealing resin 5. In the dicing process, with the cutting line CL in FIG. 10 serving as the boundary, the portion on the left side of the cutting line CL is cut off with a dicing blade. In this manufacturing method, the cutting is performed in two stages. First, as shown in FIG. 11, the first cutting is performed to a depth smaller than the dimension in the z direction of the sealing resin 5. As a result, the recessed region 132 is formed. After the first cutting, a plating layer of, for example, Sn (tin) may be formed. Next, the second cutting is performed. In the second cutting, the sealing resin 5 is cut through the entire thickness in the z direction with a dicing blade that is thinner than the dicing blade used for the first cutting. By the second cutting, dicing into a plurality of semiconductor devices A1 is realized. Also, the second cutting forms the flat regions 131 and the resin side surfaces 53.

Next, the effects of the semiconductor device A1 will be described.

According to the test by the inventors, during the first cutting shown in FIGS. 10 and 11, a phenomenon was observed where some of the plurality of first lead 1 were stretched in the second direction (the y direction in FIG. 10) at their z2-side portions in the z-direction (the portion exposed from the resin first surface 51 and the nearby portions). When this phenomenon becomes pronounced, there is a risk that adjacent first leads 1 may become undesirably electrically conductive to each other. According to the present embodiment, as shown in FIG. 7, the first width W1 of the first end edge 1111 is smaller than the second width W2 of the first wide portion 112. Thus, it is possible to reduce the stretching in the second direction (the y direction in FIG. 10). Therefore, it is possible to suppress short circuits between the first leads 1.

The second width W2 of the first wide portion 112 is larger than the first width W1. Thus, it is possible to prevent the area of the first surface 11 (the volume of the first lead 1) from becoming unduly small, while setting the first width W1 smaller than the second width W2.

The first narrow portion 111 has a tapered shape. This suppresses the formation of geometric irregularities in the first narrow portion 111, which is advantageous for mitigating the effects of stress concentration or the like.

As shown in FIG. 7, the third width W3 of the second end edge 1211 is larger than the first width W1. Thus, it is possible to avoid the rigidity at the portion where the frame portion F holds the first lead 1 in the state shown in FIG. 10 from becoming unduly low, while setting the first width W1 small. Therefore, in the method for manufacturing the semiconductor device A1, the first leads 1 can be held in the lead frame LF with proper orientation. Also, the third width W3 is larger than the second width W2. This is suitable for increasing the rigidity at the portion where the frame portion F holds the first lead 1.

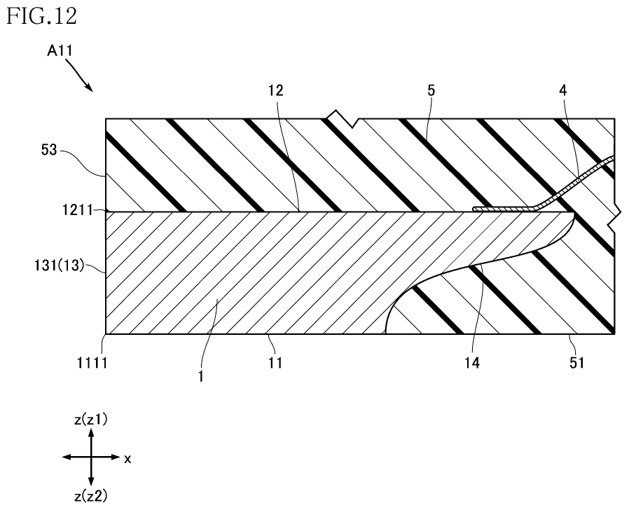

FIGS. 12 to 15 show variations and other embodiments of the present disclosure. In these figures, the elements that are identical or similar to those of the embodiment described above are denoted by the same reference signs as those used for the embodiment described above. Various parts of variations and embodiments may be selectively used in any appropriate combination as long as it is technically compatible.

First embodiment, First variation:

FIG. 12 shows a first variation of the semiconductor device A1. The semiconductor device A11 of the present variation differs from the example described above in the configuration of the first end surface 13.

The first end surface 13 of the present variation includes the flat region 131 and does not include the recessed region 132. Such a first end surface 13 is formed when, during the dicing process in the method for manufacturing the semiconductor device A11, the lead frame LF (the first leads 1 and the second lead 2) and the sealing resin 5 are cut through in the z-direction at an appropriate position by a single cutting step, rather than the two-stage cutting described above.

According to the present variation again, it is possible to suppress short circuits between the first leads 1. As understood from the present variation, the specific configuration of the first end surface 13 is not particularly limited.

The first lead 1, First variation:

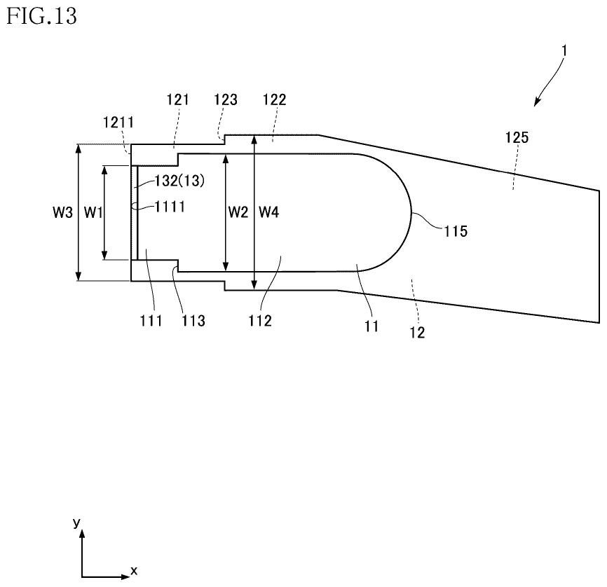

FIG. 13 shows a first variation of the first lead 1. In the first lead 1 of the present variation, the first narrow portion 111 of the first surface 11 has a constant size in the y direction. The first surface 11 has a first stepped portion 113. The first stepped portion 113 is interposed between the first narrow portion 111 and the first wide portion 112 and has a bent outline.

According to the present variation again, it is possible to suppress short circuits between the first leads 1. As understood from the present variation, the specific configuration of the first surface 11 is not particularly limited.

The first lead 1, Second variation:

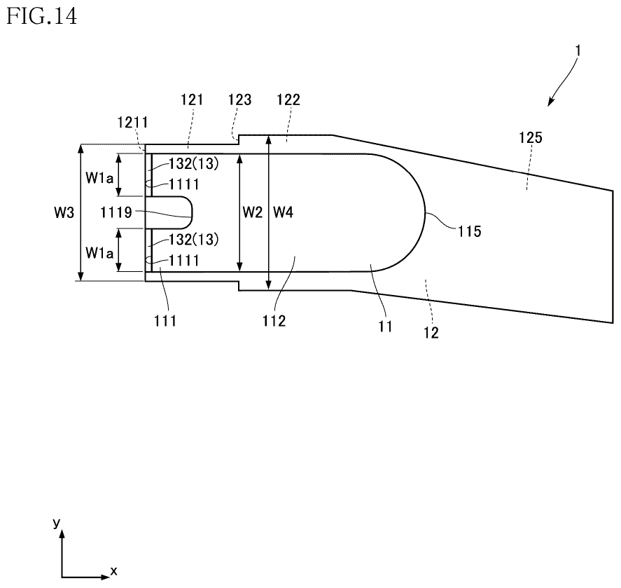

FIG. 14 shows a second variation of the first lead 1. In the first lead 1 of the present variation, the first narrow portion 111 has a recess 1119. The recess 1119 is recessed inward in the first direction (to the right side in the x direction in FIG. 14) from the first end edge 1111. The recess 1119 is located approximately at the center in the y-direction of the first end edge 1111. The first width W1 of the present variation is the sum of two widths W1a. In the present variation, the distance between the opposite edges in the second direction (the y direction in FIG. 14) of the first narrow portion 111 is constant, and is the same (or approximately the same) as the second width W2 in the illustrated example.

According to the present variation again, it is possible to suppress short circuits between the first leads 1. As understood from the above, the present variation provides a configuration where the first width W1 is made smaller than the second width W2 while the distance between the opposite edges in the second direction of the first narrow portion 111 is made the same (or approximately the same) as the second width W2.

The first lead 1, Third variation:

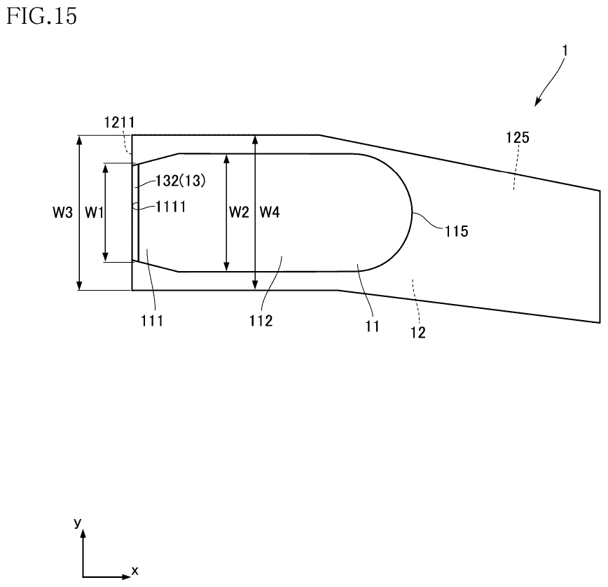

FIG. 15 shows a third variation of the first lead 1. In the first lead 1 of the present variation, the second surface 12 is not divided into the second narrow portion 121 and the second wide portion 122. In the present variation, the size in the second direction (the y direction in FIG. 15) of the second surface 12 at the portions other than the inclined portion 125 is the third width W3.

According to the present variation again, it is possible to suppress short circuits between the first leads 1. As understood from the present variation, the specific configuration of the second surface 12 is not particularly limited.

The semiconductor device according to the present disclosure is not limited to the above-described embodiments. Various modifications in design may be made freely in the specific structure of each part of the semiconductor device according to the present disclosure. The present disclosure includes embodiments described in the following clauses.
Clause 1.

A semiconductor device (A1) comprising:
a plurality of first leads (1);
a semiconductor element (3) electrically connected to the plurality of first leads (1); and
a sealing resin (5) covering a part of each of the plurality of first leads (1) and the semiconductor element (3), wherein
the sealing resin (5) includes a resin first surface (51) facing a first side in a thickness direction, a resin second surface (52) facing a second side in the thickness direction, and a resin side surface (53) located between the resin first surface (51) and the resin second surface (52) and facing outward in a first direction intersecting the thickness direction,
each of the first leads (1) includes a first surface (11) facing the first side in the thickness direction and exposed from the resin first surface (51), a second surface (12) facing the second side in the thickness direction, and a first end surface (13) located between the first surface (11) and the second surface (12) in the thickness direction, facing outward in the first direction, and exposed from the resin side surface (53),
the first surface (11) includes a first narrow portion (111) connected to the first end surface (13) and a first wide portion (112) located on an inner side in the first direction relative to the first narrow portion (111),
the first narrow portion (111) includes a first end edge (1111) adjoining the first end surface (13), and
the first end edge (1111) has a first width (W1) in a second direction orthogonal to the thickness direction and the first direction, and the first wide portion (112) has a second width (W2) in the second direction, the first width (W1) being smaller than the second width (W2).
Clause 2.

The semiconductor device (A1) according to clause 1, wherein the first narrow portion (111) has a tapered shape where a size thereof in the second direction decreases from an inner side toward an outer side in the first direction.
Clause 3.

The semiconductor device (A1) according to clause 1, wherein the first wide portion (111) has a constant size in the second direction.
Clause 4.

The semiconductor device (A1) according to clause 3, wherein the first surface (11) includes a first stepped portion (113) interposed between the first narrow portion (111) and the first wide portion (112).
Clause 5.

The semiconductor device (A1) according to clause 1, wherein the first narrow portion (111) has a constant size in the second direction.
Clause 6.

The semiconductor device (A1) according to any one of clauses 1 to 5, wherein the second surface (12) includes a second end edge (1211) adjoining the first end surface (13), and
the second end edge (1211) has a third width (W3) in the second direction, the third width (W3) being larger than the first width (W1).
Clause 7.

The semiconductor device (A1) according to clause 6, wherein the second surface (12) includes a second narrow portion (121) including the second end edge (1211), and a second wide portion (122) located on an inner side in the first direction relative to the second narrow portion (121), and
the second wide portion (122) has a fourth width (W4) in the second direction, the fourth width (W4) being larger than the third width (W3).
Clause 8.

The semiconductor device (A1) according to clause 7, wherein the second narrow portion (121) has a constant size in the second direction.
Clause 9.

The semiconductor device (A1) according to clause 8, wherein the second surface (12) includes a second stepped portion (123) interposed between the second narrow portion (121) and the second wide portion (122).
Clause 10.

The semiconductor device (A1) according to any one of clauses 7 to 9, wherein a size in the first direction of the second narrow portion (121) is larger than a size in the first direction of the first narrow portion (111).
Clause 11.

The semiconductor device (A1) according to any one of clauses 7 to 10, wherein the second wide portion (122) has a constant size in the second direction.
Clause 12.

The semiconductor device (A1) according to any one of clauses 7 to 11, wherein a size in the first direction of the second surface (12) is larger than a size in the first direction of the first surface (11).
Clause 13.

The semiconductor device (A1) according to clause 12, wherein the second surface (12) includes an inclined portion (125) connected to the second wide portion (122) on an inner side in the first direction and extending in a direction inclined with respect to the first direction.
Clause 14.

The semiconductor device (A1) according to any one of clauses 1 to 13, further comprising a second lead (2) including a third surface (21) and a fourth surface (22), the third surface (21) facing the first side in the thickness direction and exposed from the resin first surface (51), the fourth surface (22) facing the second side in the thickness direction,
wherein the semiconductor element (3) is mounted on the fourth surface (22).
Clause 15.

The semiconductor device (A1) according to clause 14, wherein the second lead (2) includes an island portion (25) located on an inner side in the first direction relative to the plurality of first leads (1), and
the semiconductor element (3) is mounted on a portion of the fourth surface (22) that is included in the island portion (25).

### REFERENCE NUMERALS

A1, A11: Semiconductor device 1: First lead
2: Second lead 3: Semiconductor element
4: Wire 5: Sealing resin
11: First surface 12: Second surface
13: First end surface 14: Intermediate surface
15: Side surface 21: Third surface
22: Fourth surface 25: Island portion
26: Corner portion 27: Connecting portion
30: Main body 31: Electrode
39: Bonding material 51: Resin first surface
52: Resin second surface 53: Resin side surface
111: First narrow portion 112: First wide portion
113: First stepped portion 115: Arc-shaped portion
121: Second narrow portion 122: Second wide portion
123: Second stepped portion 125: Inclined portion
131: Flat region 132: Recessed region
211: Center region 212: Corner region
1111: First end edge 1119: Recess
1211: Second end edge F: Frame portion
LF: Lead frame W1: First width
W2: Second width W3: Third width
W4: Fourth width

1. A semiconductor device comprising:
a plurality of first leads;
a semiconductor element electrically connected to the plurality of first leads; and
a sealing resin covering a part of each of the plurality of first leads and the semiconductor element, wherein
the sealing resin includes a resin first surface facing a first side in a thickness direction, a resin second surface facing a second side in the thickness direction, and a resin side surface located between the resin first surface and the resin second surface and facing outward in a first direction intersecting the thickness direction,
each of the first leads includes a first surface facing the first side in the thickness direction and exposed from the resin first surface, a second surface facing the second side in the thickness direction, and a first end surface located between the first surface and the second surface in the thickness direction, facing outward in the first direction, and exposed from the resin side surface,
the first surface includes a first narrow portion connected to the first end surface and a first wide portion located on an inner side in the first direction relative to the first narrow portion,
the first narrow portion includes a first end edge adjoining the first end surface, and
the first end edge has a first width in a second direction orthogonal to the thickness direction and the first direction, and the first wide portion has a second width in the second direction, the first width being smaller than the second width.

2. The semiconductor device according to claim 1, wherein the first narrow portion has a tapered shape where a size thereof in the second direction decreases from an inner side toward an outer side in the first direction.

3. The semiconductor device according to claim 1, wherein the first wide portion has a constant size in the second direction.

4. The semiconductor device according to claim 3, wherein the first surface includes a first stepped portion interposed between the first narrow portion and the first wide portion.

5. The semiconductor device according to claim 1, wherein the first narrow portion has a constant size in the second direction.

6. The semiconductor device according to claim 1, wherein the second surface includes a second end edge adjoining the first end surface, and
the second end edge has a third width in the second direction, the third width being larger than the first width.

7. The semiconductor device according to claim 6, wherein the second surface includes a second narrow portion including the second end edge, and a second wide portion located on an inner side in the first direction relative to the second narrow portion, and
the second wide portion has a fourth width in the second direction, the fourth width being larger than the third width.

8. The semiconductor device according to claim 7, wherein the second narrow portion has a constant size in the second direction.

9. The semiconductor device according to claim 8, wherein the second surface includes a second stepped portion interposed between the second narrow portion and the second wide portion.

10. The semiconductor device according to claim 7, wherein a size in the first direction of the second narrow portion is larger than a size in the first direction of the first narrow portion.

11. The semiconductor device according to claim 7, wherein the second wide portion has a constant size in the second direction.

12. The semiconductor device according to claim 7, wherein a size in the first direction of the second surface is larger than a size in the first direction of the first surface.

13. The semiconductor device according to claim 12, wherein the second surface includes an inclined portion connected to the second wide portion on an inner side in the first direction and extending in a direction inclined with respect to the first direction.

14. The semiconductor device according to claim 1, further comprising a second lead including a third surface and a fourth surface, the third surface facing the first side in the thickness direction and exposed from the resin first surface, the fourth surface facing the second side in the thickness direction,
wherein the semiconductor element is mounted on the fourth surface.

15. The semiconductor device according to claim 14, wherein the second lead includes an island portion located on an inner side in the first direction relative to the plurality of first leads, and
the semiconductor element is mounted on a portion of the fourth surface that is included in the island portion.
